(19) United States
(12) Patent Application Publication
(10) Pub. No.: US 2008/0206986 A1
(43) Pub. Date: Aug. 28, 2008

(54) METHOD OF FORMING A COPPER-BASED METALLIZATION LAYER INCLUDING A CONDUCTIVE CAP LAYER BY AN ADVANCED INTEGRATION REGIME

(76) Inventors: Axel Preusse, Radebeul (DE); Berit Freudenberg, Dresden (DE); Michael Friedemann, Dresden (DE)

Correspondence Address: J. Mike Amerson;Williams, Morgan & Amerson, P.C., Suite 1100, 10333 Richmond, Houston, TX, 77042, US

(21) Appl. No.: 11/871,247

(22) Filed: Oct. 12, 2007

(30) Foreign Application Priority Data
Feb. 28, 2007 (DE) 10 2007 009 912.8

(51) Int. Cl. H01L 21/441

(52) U.S. Cl. 438/653; 257/E21.477

(57) ABSTRACT

By appropriately designing a plurality of deposition steps and intermediate sputter processes, the formation of a barrier material within a via opening may be accomplished on the basis of a highly efficient process strategy that readily integrates conductive cap layers formed above metal-containing regions into well-approved process sequences.

### BACKGROUND OF THE INVENTION

1. Field of the Invention

Generally, the present disclosure relates to the formation of microstructures, such as advanced integrated circuits, and, more particularly, to the formation of conductive structures, such as copper-based metallization layers, and techniques to reduce electromigration and other stress-induced mass transport effects during operation.

2. Description of the Related Art

In the fabrication of modern microstructures, such as integrated circuits, there is a continuous drive to steadily reduce the feature sizes of microstructure elements, thereby enhancing the functionality of these structures. For instance, in modern integrated circuits, minimum feature sizes, such as the channel length of field effect transistors, have reached the deep sub-micron range, thereby increasing performance of these circuits in terms of speed and/or power consumption. As the size of individual circuit elements is reduced with every new circuit generation, thereby improving, for example, the switching speed of the transistor elements, the available floor space for interconnect lines electrically connecting the individual circuit elements is also decreased. Consequently, the dimensions of these interconnect lines are also reduced to compensate for a reduced amount of available floor space and for an increased number of circuit elements provided per unit die area, as typically the number of interconnections required increases more rapidly than the number of circuit elements. Thus, a plurality of stacked “wiring” layers, also referred to as metallization layers, are usually provided, wherein individual metal lines of one metallization layer are connected to individual metal lines of an overlying or underlying metallization layer by so-called vias. Despite the provision of a plurality of metallization layers, reducing the dimensions of the interconnect lines is also necessary to comply with the enormous complexity of, for instance, modern CPUs, memory chips, ASICs (application specific ICs) and the like. The reduced cross-sectional area of the interconnect structures, possibly in combination with an increase of the static power consumption of extremely scaled transistor elements, may result in considerable current densities in the metal lines, which may even increase with every new device generation.

Advanced integrated circuits, including transistor elements having a critical dimension of 0.1 μm and even less, may, therefore, typically be operated at significantly increased current densities of up to several Ka/cm² in the individual interconnect structures. This increased current density occurs despite the provision of a relatively large number of metallization layers, owing to the significant number of circuit elements per unit area. Operating the interconnect structures at elevated current densities, however, may entail a plurality of problems related to stress-induced line degradation, which may finally lead to a premature failure of the integrated circuit. One prominent phenomenon in this respect is the current-induced mass transport in metal lines and vias, also referred to as “electromigration.” Electromigration is caused by momentum transfer of electrons to the ion cores, resulting in a net momentum in the direction of electron flow. In particular, at high current densities, a significant collective motion or directed diffusion of atoms may occur in the interconnect metal, wherein the presence of respective diffusion paths may have a substantial influence on the displaced amount of mass resulting from the momentum transfer. Thus, electromigration may lead to the formation of voids within and hillocks next to the metal interconnect, thereby resulting in reduced performance and reliability or complete failure of the device. For instance, aluminum lines embedded into silicon dioxide and/or silicon nitride are frequently used as metal for metallization layers, wherein, as explained above, advanced integrated circuits having critical dimensions of 0.1 μm or less, may require significantly reduced cross-sectional areas of the metal lines and, thus, increased current densities, which may render aluminum less attractive for the formation of metallization layers.

Consequently, aluminum is being replaced by copper and copper alloys, a material with significantly lower resistivity and improved resistance to electromigration even at considerably higher current densities compared to aluminum. The introduction of copper into the fabrication of microstructures and integrated circuits comes along with a plurality of severe problems residing in copper's characteristic to readily diffuse in silicon dioxide and a plurality of low-k dielectric materials, which are typically used in combination with copper in order to reduce the parasitic capacitance within complex metallization layers. In order to provide the necessary adhesion and to avoid the undesired diffusion of copper atoms into sensitive device regions, it is, therefore, usually necessary to provide a barrier layer between the copper and the dielectric material in which the copper-based interconnect structures are embedded. Although silicon nitride is a dielectric material that effectively prevents the diffusion of copper atoms, selecting silicon nitride as an interlayer dielectric material is less than desirable, since silicon nitride exhibits a moderately high permittivity, thereby increasing the parasitic capacitance of neighboring copper lines, which may result in non-tolerable signal propagation delays. Hence, a thin conductive barrier layer that also imparts the required mechanical stability to the copper is usually formed to separate the bulk copper from the surrounding dielectric material, thereby reducing copper diffusion into the dielectric materials and also reducing the diffusion of unwanted species, such as oxygen, fluorine and the like, into the copper. Furthermore, the conductive barrier layers may also provide highly stable interfaces with the copper, thereby reducing the probability for significant mass transport at the interface, which is typically a critical region in view of increased diffusion paths. Currently, tantalum, titanium, tungsten and their compounds, with nitrogen and silicon and the like, are preferred candidates for a conductive barrier layer, wherein the barrier layer may comprise two or more sub-layers of different composition so as to meet the requirements in terms of diffusion suppressing and adhesion properties.

Another characteristic of copper significantly distinguishing it from aluminum is the fact that copper may not be readily deposited in larger amounts by chemical and physical vapor deposition techniques, in addition to the fact that copper may not be efficiently patterned by anisotropic dry etch processes, thereby requiring a process strategy that is commonly referred to as the damascene or inlaid technique. In the damascene process, first a dielectric layer is formed which is then patterned to include trenches and/or vias which are subsequently filled with copper, wherein, as previously noted, prior to filling in the copper, a conductive barrier layer is formed on sidewalls of the trenches and vias. The deposition of the bulk copper material into the trenches and vias is usually accomplished by wet chemical deposition processes, such as electroplating and electroless plating, thereby requiring the reliable filling of vias with an aspect ratio of 5 and more with a diameter of 0.3 μm or even less in combination with trenches having a width ranging from 0.1 μm to several μm. Electrochemical deposition processes for copper are well established in the field of electronic circuit board fabrication. However, the void free filling of high aspect ratio vias is an extremely complex and challenging task, wherein the characteristics of the finally obtained copper-based interconnect structure significantly depend on process parameters, materials and geometry of the structure of interest. Since the geometry of interconnect structures is substantially determined by the design requirements and may, therefore, not be significantly altered for a given microstructure, it is of great importance to estimate and control the impact of materials, such as conductive and non-conductive barrier layers, of the copper microstructure and their mutual interaction on the characteristics of the interconnect structure so as to insure both high yield and the required product reliability. In particular, it is important to identify, monitor and reduce degradation and failure mechanisms in interconnect structures for various configurations to maintain device reliability for every new device generation or technology node.

Accordingly, a great deal of effort has been made in investigating the degradation of copper interconnects, especially in combination with low-k dielectric materials having a relative permittivity of 3.1 or even less, in order to find new materials and process strategies for forming copper-based lines and vias with a low overall permittivity. Although the exact mechanism of electromigration in copper lines is still not quite fully understood, it turns out that voids positioned in and on sidewalls and especially at interfaces to neighboring materials may have a significant impact on the finally achieved performance and reliability of the interconnects.

One failure mechanism which is believed to significantly contribute to a premature device failure is the electromigration-induced material transport, particularly along an interface formed between the copper and a dielectric cap layer, which may be provided after filling in the copper material in the trenches and via openings, the sidewalls of which are coated by the conductive barrier materials. In addition to maintaining copper integrity, the dielectric cap layer may usually act as an etch stop layer during the formation of the via openings in the interlayer dielectric. Frequently used materials are, for example, silicon nitride and silicon carbon nitride, which exhibit a moderately high etch selectivity to typically employed interlayer dielectrics, such as a plurality of low-k dielectric materials, and also suppress the diffusion of copper into the interlayer dielectric. Recent research results seem to indicate, however, that the interface formed between the copper and dielectric cap layer is a major diffusion path for material transport during operation of the metal interconnect.

Consequently, a plurality of alternatives have been developed in an attempt to enhance the interface characteristics between the copper and the cap layer having the capability of reliably confining the copper and maintaining its integrity. For example, it has been proposed to selectively provide conductive materials on top of the copper-containing region, which may exhibit superior electromigration performance while not unduly increasing the overall resistance of the corresponding metal line. For instance, a compound of cobalt/tungsten/phosphorous, cobalt/tungsten/boron and the like have proven to be promising candidates for conductive cap layers, which may significantly reduce electromigration effects within a corresponding metal line. Although these materials may provide significant performance advantages with respect to electromigration effects, significant efforts may be associated with a respective process flow based on well-established inlaid techniques, when corresponding metal alloys have to be integrated into the corresponding metallization scheme. For instance, the respective metal alloys, although providing significant advantages with respect to electromigration, may result in a reduced conductivity at critical portions, at which neighboring metallization layers are connected by corresponding vias. That is, forming a corresponding via opening connecting to the lower lying metal region having formed thereon the corresponding conductive cap layer, the process sequence based on well-established techniques, such as deposition of appropriate barrier layers within the via opening, may result in an increased overall series resistance, while an aggressive material reduction at the via bottom may give rise to a corresponding damage of the copper material provided under the conductive cap layer. Thus, corresponding highly complex process steps may be required so as to reduce undue copper damage while nevertheless reducing undue increase of the series resistance of the corresponding electrical connection.

The present disclosure is directed to various methods that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure relates to enhanced manufacturing techniques in forming electrical connections between neighboring metallization layers wherein an efficient integration scheme may provide enhanced electromigration performance while nevertheless not unduly affecting the overall electrical performance of the corresponding connection.

According to one aspect, a method comprises forming an opening in a dielectric layer stack formed above a metal-containing region, the metal-containing region comprising a conductive cap layer forming at least one interface with the dielectric layer stack. The method further comprises forming a first barrier layer on sidewalls of the opening and performing a sputter process to remove material from a bottom of the opening and to deposit at least part of the material on the sidewalls. An electroless deposition process is performed using the deposited material as catalyst to deposit a second barrier layer. Finally, the opening is filled with a material containing a metal.

According to another aspect, a method comprises forming an opening in a dielectric layer stack formed above a metal-containing region, the metal-containing region comprising a conductive cap layer forming at least one interface with the dielectric layer stack. The method further comprises performing a sputter process to remove material of the conductive cap layer and to deposit part of the removed material at a lower portion of the sidewalls. A barrier layer is deposited at the lower portion using an electroless deposition process with the deposited material as activation material. Finally, the opening is filled with a material containing a metal.

According to yet another aspect, a method comprises forming a conductive cap layer above a copper-containing metal region provided in a dielectric material and forming a dielectric layer stack above the conductive cap layer. In the dielectric layer stack, an opening is formed to uncover part of the conductive cap layer. Moreover, a first conductive barrier layer is formed on sidewalls of the opening. Additionally, a second conductive barrier layer is formed covering the first conductive barrier layer at a lower portion of the opening using an electroless deposition process. Finally, the opening is filled with a material containing a metal.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1g schematically illustrate cross-sectional views of a portion of a metallization layer of a semiconductor device during various manufacturing stages in forming a via connecting to a metal region including a conductive cap layer according to illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The subject matter of the present disclosure is directed to an efficient process strategy for providing metallization structures, such as copper-based metal lines and respective vias connecting thereto, wherein the respective conductive cap layers comprised of appropriate metal alloys may be used in order to enhance the electromigration performance or reduce any other stress-induced mass transport phenomena in metal lines of advanced semiconductor devices. As previously explained, although the advantageous characteristics of respective metal alloys may provide enhanced electromigration performance, thereby allowing increased current densities within the respective interconnect structures, significant efforts in terms of process complexity, throughput and the like may render conventional approaches less attractive. Furthermore, reduced electrical performance of corresponding critical connections, i.e., the transition area between a metal region and a corresponding via, may be obtained, since, at this critical area, the conductive cap layer may have to form an interface with the corresponding barrier layer in the via opening, thereby possibly contributing to an enhanced electrical resistance and/or causing undue damage and, thus, reduced reliability of the corresponding copper-containing region. Respective issues associated with conventional techniques may arise from moderately aggressive process steps, such as wet chemical etch processes, plasma-based etch processes and the like, in order to appropriately form the opening into the lower lying metal region in an attempt to not unduly damage the copper-containing region and also provide a tolerable series resistance. Contrary to this approach, the embodiments disclosed herein may provide an efficient process strategy by appropriately combining respective process steps required for forming appropriate barrier layers in a corresponding via opening, wherein the combination of these process steps may be controlled such that a plurality of individual steps, each of which may contribute to the overall process result in a highly controllable manner, may commonly result in a desired degree of integrity of the barrier material. Consequently, increased overall controllability of the corresponding process sequence may be accomplished, thereby providing an enhanced process throughput compared to conventional approaches while nevertheless increasing electrical performance and electromigration performance. That is, the conductive cap layer, which may be comprised of compounds such as cobalt/tungsten/phosphorous (CoWP), cobalt/tungsten/boron (CoWB), nickel/molybdenum/boron (NiMoB), nickel/molybdenum/phosphorous (NiMoP) and the like, may be provided such that, in particular, failure prone locations in metallization layers, such as the transition area between vias and metal lines, may be significantly reinforced in that intact barrier layers are provided.

It should be appreciated that the embodiments disclosed herein may provide an efficient scalable process sequence, since the corresponding manufacturing processes may have to be performed anyway during the formation of the corresponding via opening and the subsequent deposition of respective barrier materials, wherein, however, controlling a parameter of the respective processes may be performed on the basis of pre-established target values so as to reduce negative effects of each individual process step in terms of damage of the metal material while nevertheless obtaining a process result corresponding to the respective target values in terms of layer thickness, material composition and the like. Hence, the subject matter disclosed herein may be applied advantageously in extremely scaled devices, such as semiconductor devices of the 32 nm technology node and less.

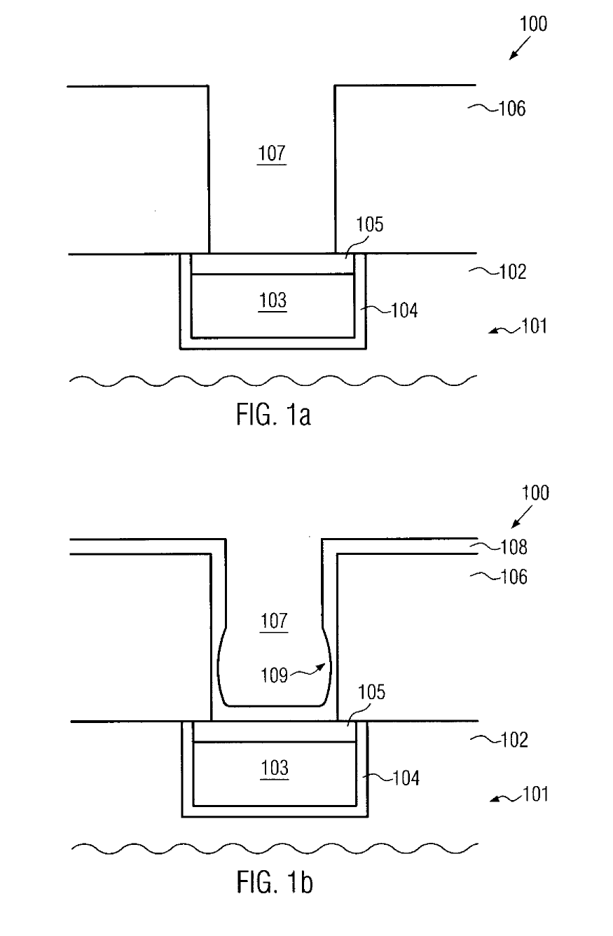

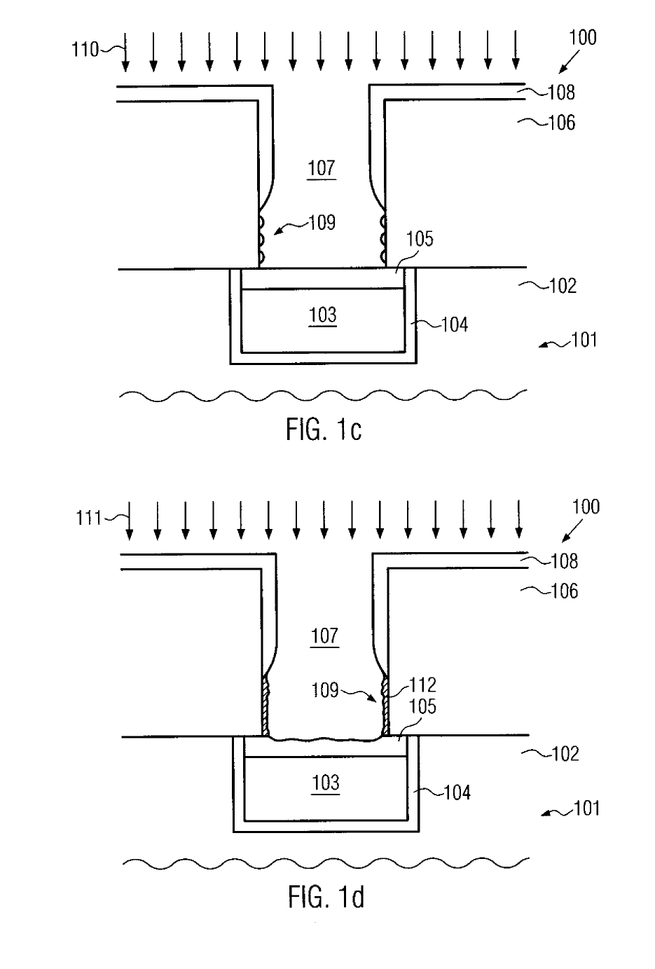

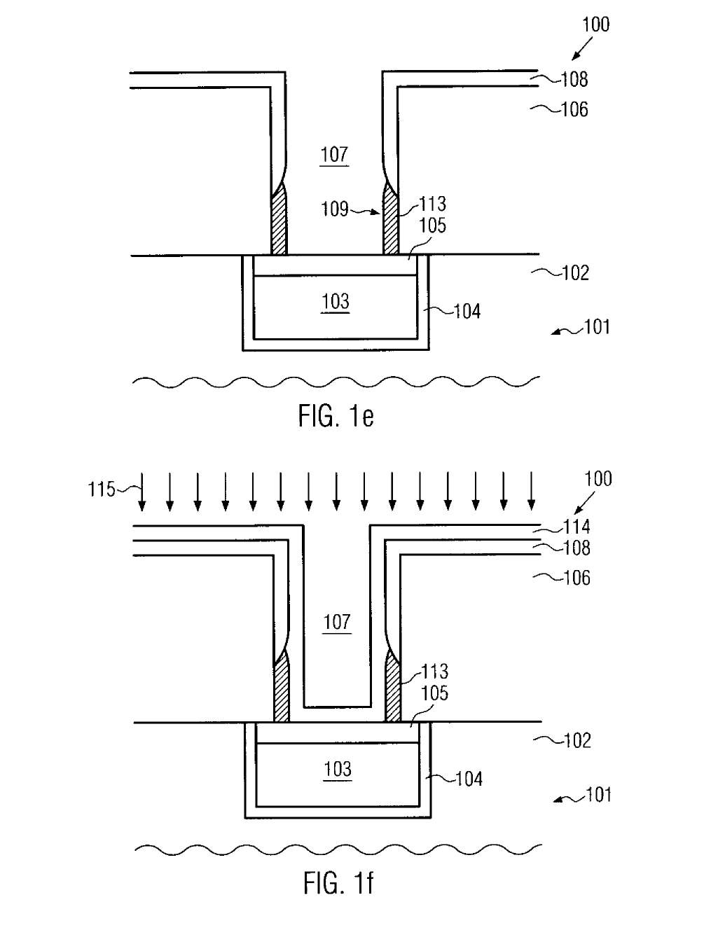

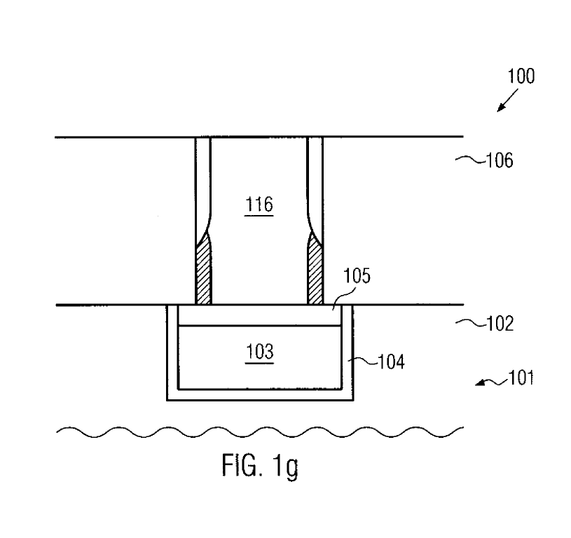

FIG. 1a schematically illustrates a cross-sectional view of a semiconductor device 100 during a moderately advanced manufacturing stage. The semiconductor device 100 comprises a substrate 101, which may represent any substrate that is appropriate for the formation of circuit elements thereon. For instance, the substrate 101 may be a bulk semiconductor substrate, or an insulating substrate having formed thereon a semiconductor layer, such as a crystalline silicon region, a silicon/germanium region, or any other III-V or II-VI semiconductor compound, and the like. Typically, the substrate 101 may represent a carrier having formed thereon a large number of circuit elements, such as transistors, capacitors and the like, as required for defining a complex integrated circuit. These circuit elements may be electrically connected in accordance with a specific circuit design by means of one or more metallization layers, wherein, for convenience, only a portion of a respective metallization layer stack may be shown and described herein. It may, however, be readily appreciated that the concept of enhancing the electromigration or stress-induced mass transport phenomena by using a conductive cap layer in combination with enhanced process strategies for forming a via opening connecting thereto may be applied to any complex device configuration including a plurality of metallization layers. In illustrative embodiments, the metal regions or lines may be copper-based metal lines and regions, which in particular embodiments may be formed in a low-k dielectric material, which may be understood as a material having a dielectric constant of 3.0 or less.

The semiconductor device 100 may comprise a dielectric layer 102, and may represent the dielectric material of a metallization layer or any other interlayer dielectric material and the like. In highly advanced semiconductor devices, the dielectric layer 102 may comprise a low-k dielectric material in order to reduce the parasitic capacitance between neighboring metal lines. Furthermore, a metal region 103 is formed in the dielectric layer 102 and may be comprised of a metal-containing material, such as a copper-containing metal, which may typically be confined on sidewall portions thereof and the bottom by a barrier layer 104. As previously explained, when copper or other highly diffusive material compounds are present in the metal region 103, the barrier layer 104 may have to provide enhanced adhesion, diffusion blocking characteristics and the like. Consequently, the barrier layer 104 may typically be comprised of two or more material layers of different composition so as to maintain the integrity of the metal region 103 and the surrounding dielectric material of the layer 102, while at the same time providing the required stability of the corresponding interface in terms of stress-induced mass transport phenomena. For example, tantalum nitride in combination with tantalum may frequently be used for copper-based metallization regimes. However, many other material compositions may be used in accordance with device requirements. Moreover, the metal region 103 is further confined by a conductive cap layer 105 that may be formed by an appropriately selected metal alloy, for instance, a composition as previously described. Furthermore, the semiconductor device 100 may comprise a second dielectric layer 106, which may be provided in the form of a layer stack, wherein at least one or more material layers may be provided in the form of a low-k dielectric material, depending on the device requirements. In some illustrative embodiments, the dielectric layer 102 may represent the dielectric material of a further metallization layer including the dielectric material for a via layer, in which respective vias are to be formed to provide electrical connection between the metal region 103, representing a metal line or any other metal region of a first metallization layer, and respective metal lines to be formed in a portion of the dielectric layer 106. In other cases, the dielectric layer 106 may represent the material of a via layer, wherein respective metal lines of a next metallization level may have to be formed by providing a separate dielectric material in a further advanced manufacturing stage. Furthermore, in this manufacturing stage, the dielectric layer 106 may include an opening 107 extending to the conductive cap layer 105.

A typical process flow for forming the semiconductor device 100 as shown in FIG. 1a may comprise the following processes. After any well-established process techniques for forming circuit elements and/or microstructure elements in and on the substrate 101, the dielectric layer 102 may be formed, which may comprise two or more sub-layers, depending on device requirements. For example, the dielectric layer 102 may be formed on the basis of well-established plasma enhanced chemical vapor deposition (PECVD) techniques, when comprising silicon dioxide, silicon nitride and the like. However, other deposition techniques may be used, such as spin-on techniques for low-k polymer materials and the like. Thereafter, an appropriately designed lithography process may be performed in order to provide an appropriate resist mask to be used to pattern a respective trench on the basis of well-established anisotropic etch techniques. Next, the barrier layer 104 may be formed by any appropriate deposition technique, such as sputter deposition, chemical vapor deposition (CVD), atomic layer deposition (ALD) and the like. For instance, the barrier layer 104 may be comprised of conductive materials, such as, tantalum, tantalum nitride, titanium, titanium nitride, tungsten, tungsten nitride or any other appropriate materials, wherein typically two or more different material compositions and layers may be provided as is required for achieving the desired adhesion and diffusion blocking characteristics. It should be appreciated that the barrier layer 104 may also be formed on the basis of respective process regimes as will be described with reference to the barrier layer 108 and any further barrier layers to be formed thereon. For example, the barrier layer 104 may comprise, in addition to the above-identified materials, one or more of cobalt/tungsten/phosphorous (CoWP), cobalt/tungsten/boron (CoWB), nickel/molybdenum/boron (NiMoB) and nickel/molybdenum/phosphorous (NiMoP), at least as an uppermost layer thereof.

After the deposition of the barrier layer 104, a copper seed layer may be deposited by any appropriate deposition techniques, such as sputter deposition, electroless deposition and the like, if a copper-based material is to be filled in on the basis of well-established wet chemical deposition techniques. Corresponding recipes for forming a seed layer are well established in the art. Thereafter, the metal material for the region 103 may be deposited on the basis of, for instance, electroplating, electroless plating and the like, wherein typically a certain amount of excess material may be provided in order to ensure a reliable filling of the corresponding trench. The corresponding excess material may be removed on the basis of chemical mechanical polishing (CMP), electrochemical polishing and the like, on the basis of well-established recipes. For example, a substantially planar surface topology may be provided by the CMP process and subsequently an electrochemical etch process may be performed for removing further residual material and forming a recess in the corresponding metal region 103. In other embodiments, the CMP process used for planarizing the surface topology may be continued on the basis of the specified over-polish time so as to form a recess in the region 103, if required. During the corresponding process sequence for planarizing the surface topology and/or for forming a recess, if required, excess material of the barrier layer 104 may also be removed. In some illustrative embodiments, a catalyst material may then be deposited, which may be accomplished on the basis of highly selective deposition techniques, for instance by using an electroless plating process, thereby selectively preparing the surface of the metal region 103 for the deposition of the material of the conductive cap layer 105. It should be appreciated, however, that many other process strategies may be used to allow a highly selective deposition of the material of the conductive cap layer 105 on the basis of wet chemical deposition recipes. Hence, thereafter, the cap layer 105 may be formed on the basis of an electrochemical process, thereby providing a strong interface with the metal region 103, which may have enhanced characteristics in terms of electromigration behavior, as previously explained. After the deposition of the cap layer 105, any excess material, which may possibly have been formed during the wet chemical deposition process, may be removed and the surface topography of the device 100 may be planarized, if required, on the basis of well-established techniques, such as CMP, electrochemical etching and the like.

Next, the dielectric layer 106, typically a dielectric layer stack, may be formed on the conductive cap layer 105 and the dielectric layer 102. For instance, depending on the desired material composition of the dielectric layer 106, respective deposition techniques may be used, wherein typically an etch stop layer may be provided as a first layer, as will be described later on, while, in advanced manufacturing techniques, material of the layer 106 may be directly formed on the conductive cap layer 106. Thereafter, a corresponding patterning process sequence may be performed to form the opening 107 in the dielectric layer 106, wherein typically well-established lithography processes in combination with sophisticated etch techniques may be used. In particular, the dielectric layer stack 106 may comprise a dielectric material and an etch stop material. The dielectric material 106 may represent any appropriate dielectric material in accordance with device requirements, while the etch stop layer may be selected so as to have a high etch selectivity during a corresponding anisotropic etch process for forming an opening 107 in the dielectric material. It should be appreciated that the etch stop layer may be selected with respect to layer thickness and material composition so as to provide the desired etch stop characteristics, since efficient confinement of copper and copper alloys in the metal region 103 may be accomplished on the basis of the conductive cap layer 105. Thus, even dielectric materials of moderately low permittivity may be used, as long as a respective etch selectivity may be provided. In some illustrative embodiments, the etch stop layer may even be provided as a laterally restricted layer, in order to cover an area corresponding to the opening 107, while the remainder of the dielectric material 106 and conductive cap layer 105 may remain uncovered, thereby reducing the overall permittivity of the resulting dielectric layer stack.

As illustrated in FIG. 1b, the first barrier layer 108 may be formed on the basis of an appropriate deposition technique, such as physical vapor deposition (PVD), chemical vapor deposition (CVD), self-limiting CVD processes, also referred to as atomic layer deposition (ALD), electrochemical deposition techniques and the like. In this way, the opening 107 and horizontal portions of the dielectric layer 106 may be covered by a first barrier layer 108, comprised of any appropriate material, such as tantalum nitride and the like. In some illustrative embodiments, the first barrier layer 108 may be deposited by a process performed in an ambient that enables the creation of a corresponding sputter atmosphere so as to controllably remove material from the bottom of the opening 107. For example, the deposition process may be performed as a sputter deposition process, in which one or more appropriate species, such as tantalum and nitrogen, may be deposited on exposed surface portions of the opening 107 and the layer 106 on the basis of well established recipes. The deposition process 109 may be a first process of a plurality of deposition processes so as to form the first barrier layer 108, which may represent one of two or more barrier components to be formed within the opening 107.

However, as schematically illustrated in FIG. 1b, the deposition of the first barrier layer 108, in many cases, leads on an uneven covering of the sidewalls in a lower portion 109 of the opening 107 such that the thickness of the barrier layer 108 in this region is insufficient.

FIG. 1c schematically illustrates the device 100 during a first sputter process 110, which is performed in some illustrative embodiments in situ with the deposition process described above in order to controllably remove material from the bottom of the opening 107. Thus, the process 110 may be established in the same process chamber, for instance, by applying a bias voltage to the substrate 101 in order to obtain a highly directional ion bombardment at the bottom of the opening 107, thereby releasing corresponding material previously deposited and, finally, uncovering the conductive cap layer 105. Furthermore, the respective sputter process 110 may result in the release of any contaminants, such as, oxygen, fluorine and the like, which may be present in minute amounts due to any preceding processes, for instance, a respective etch process for forming the opening 107. A portion of the material released by the process 110 may re-deposit on sidewalls of the opening 107, particularly at a lower portion 109, while highly volatile species, such as oxygen and fluorine and the like, may nevertheless be released to a certain degree into the sputter ambient and may be removed. Even if tiny amounts of these contaminants may re-deposit within the opening 107, less critical areas, such as the sidewall portions thereof, may be involved as deposition areas, thereby contributing to a displacement of respective contaminants from the critical bottom area to the less critical sidewall areas. Due to the re-deposition of material at the lower portion 109 of the sidewalls, step coverage can be enhanced. However, there is still no sufficient layer formation. It should be appreciated that respective process parameters for the first deposition process and the subsequent sputter process 110 may be established on the basis of respective test runs in order to identify the corresponding deposition rates and etch rates for a specific material composition and device geometry.

As illustrated in FIG. 1d, a further sputter process 111 is performed in which material from the conductive cap layer 105 is removed and deposited on the sidewalls at a lower portion 109 of the opening 107. In this way, an activation layer 112 is formed based on the conductive cap layer material. The sputter process 111 may be performed using the same or different process parameters than sputter process 110. The sputter process 111 is controlled so that a portion of the conductive cap 105 will be maintained. Furthermore, the sputter process 111 may yield an activation layer 112 on the lower portion 109 of the sidewalls. Although the activation layer may fully cover first barrier layer 108 at the lower portion of the opening 107, however, a complete coverage is not required as long as there is sufficient material deposited on the sidewalls to function as a catalyst for a subsequent electroless deposition process so that, finally, an intact barrier layer will be obtained.

FIG. 1e illustrates an electroless deposition process, wherein the material of the activation layer 112 is used as a catalyst for forming a second barrier layer 113. At the same time, the electroless deposition process may also increase the thickness of conductive cap layer 105 compared to the previous step. Thus, the present method allows the use of conventional sputter techniques for forming the opening 107 and barrier layer, while permitting obtaining an intact barrier due to a kind of repair process with regard to critical regions at the lower portions of the opening 107.

In a subsequent step, as illustrated in FIG. 1f, a metallic layer 114 is deposited during a deposition process 115. This deposition process 115 may be performed using a seed sputter process or a direct-on-barrier plating process. In particular, a conventional copper (Cu) seed sputter process may be employed, resulting in a copper (Cu) seed layer 114. Also, a combination of a seed sputter process and an electrolytic or electroless plating process may be used in order to perform so-called seed enhancement or seed repair, as known in the art.

FIG. 1g schematically illustrates the device 100 in a further advanced manufacturing stage. Here, a highly conductive material, such as a copper-based material, is filled in the opening 107, thereby forming a respective metal region 116, which may represent a corresponding metal line or a via opening connecting to the underlying metal region 103. The metal region 116 may be formed on the basis of well-established deposition techniques, such as electroplating, electroless plating or any combinations thereof. As a consequence, the metal region 116 may provide a highly reliable connection to the metal region 103, wherein a corresponding series resistance may be substantially defined by the overall dimensions and by the thickness of the conductive cap layer 105.

The filling of the opening may be followed by a well-established planarization process, such as conventional slurry polishing or CMP. After the planarization step, a conductive cap may be formed on top of the metal region 116 using techniques as described above in the context of conductive cap layer 105.

As a result, the subject matter disclosed herein addresses the need for preserving the electrical performance of metallization structures at the transition from one metallization level to another, wherein electromigration is reliably suppressed due to an intact barrier structure. Furthermore, process steps may be used as are typically required for depositing the desired material composition of the barrier layer with intermediate sputter processes, thereby substantially not contributing to process complexity, while substantially avoiding additional process steps except for minor changes and adaptations in order to establish the respective sputter and plating ambient, which may be accomplished in an efficient in situ sequence. Consequently, the above-described process sequence is scaleable for any further device generations and may be readily integrated into the respective process strategies without additional complexity. Furthermore, the corresponding process sequence may result in a reduced degree of contamination at the respective via bottom connecting to the highly conductive metal material.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming an opening in a dielectric layer stack formed above a metal-containing region, said-metal containing region comprising a conductive cap layer forming at least one interface with said dielectric layer stack, the opening comprising a plurality of sidewalls;
forming a first barrier layer on the sidewalls of said opening;
performing a sputter process to remove material from a bottom of said opening and to deposit at least part of said removed material on said sidewalls;
performing an electroless deposition process using said deposited, removed material as catalyst to deposit a second barrier layer; and
filling said opening with a conductive material.

2. The method of claim 1, wherein said first barrier layer is formed by a physical vapor deposition process.

3. The method of claim 1, further comprising forming a metallic layer on at least one of the first barrier layer and the second barrier layer.

4. The method of claim 3, wherein said metallic layer is formed using at least one of a seed sputter process and a direct plating process.

5. The method of claim 3, wherein said metallic layer comprises copper.

6. The method of claim 1, wherein said opening is filled using at least one of an electroplating process and an electroless plating process.

7. The method of claim 1, further comprising controlling said sputter process to maintain coverage of said sidewall by said first barrier layer.

8. The method of claim 1, further comprising controlling said sputter process to provide an activation layer on said sidewalls up to a target height from the bottom of said opening.

9. The method of claim 1, wherein said conductive cap layer comprises at least one of the following materials: a compound comprised of cobalt, tungsten and phosphorous (CoWP); a compound comprised of cobalt, tungsten and boron (CoWB); a compound comprised of nickel, molybdenum and boron (NiMoB); and a compound comprised of nickel, molybdenum and phosphorous (NiMoP).

10. The method of claim 1, wherein said conductive material is a metal.

11. The method of claim 1, wherein said metal-containing region represents a metal line in a metallization layer of a semiconductor device.

12. The method of claim 1, further comprising forming a trench in said dielectric layer stack and filling said opening and said trench in a common process.

13. The method of claim 1, wherein said removed material is sputtered off from an exposed portion of said conductive cap layer.

14. A method, comprising:
forming an opening in a dielectric layer stack formed above a metal-containing region, said metal-containing region comprising a conductive cap layer forming at least one interface with said dielectric layer stack;
performing a sputter process to remove material of said conductive cap layer and to deposit part of said removed material at a lower portion of said sidewalls;
depositing a barrier layer on at least said lower portion of said sidewalls using an electroless deposition process with said deposited material as activation material; and
filling said opening with a conductive material.

15. The method of claim 14, wherein said sputter process is preceded by a deposition process to deposit a barrier layer on said sidewalls.

16. The method of claim 15, wherein said deposition process is a physical vapor deposition process.

17. The method of claim 14, wherein said sputter process is controlled to maintain a portion of said conductive cap layer when removing material of said conductive cap layer.

18. The method of claim 14, wherein said conductive cap layer comprises at least one of the following materials: a compound comprised of cobalt, tungsten and phosphorous (CoWP); a compound comprised of cobalt, tungsten and boron (CoWB); a compound comprised of nickel, molybdenum and boron (NiMoB); and a compound comprised of nickel, molybdenum and phosphorous (NiMoP).

19. A method, comprising:
forming a conductive cap layer above a copper-containing metal region provided in a dielectric material;
forming a dielectric layer stack above said conductive cap layer;
forming an opening in said dielectric layer stack to uncover part of said conductive cap layer, the opening comprising a plurality of sidewalls;
forming a first conductive barrier layer on the sidewalls of said opening;
forming a second conductive barrier layer covering said first conductive barrier layer at a lower portion of said opening using an electroless deposition process; and
filling said opening with a conductive material.

20. The method of claim 19, wherein said second conductive barrier layer is formed using sputtered material from said conductive cap layer as a catalyst.
